(19) United States
(12) Patent Application Publication
(10) Pub. No.: US 2026/0246862 A1
(43) Pub. Date: Aug. 20, 2026

(54) FOLDABLE ELECTRONIC DEVICE COMPRISING ANTENNA MODULE

(71) Applicant: Samsung Electronics Co., Ltd., Suwon-si (KR)

(72) Inventors: Jongho PARK, Suwon-si (KR); Minsoo KIM, Suwon-si (KR); Yongwoon KIM, Suwon-si (KR); Taejeong KIM, Suwon-si (KR); Jaehyun BAE, Suwon-si (KR); Soogyu LEE, Suwon-si (KR); Yonggil HAN, Suwon-si (KR)

(21) Appl. No.: 19/640,885

(22) Filed: Apr. 7, 2026

Related U.S. Application Data
(63) Continuation of application No. PCT/KR2024/011633, filed on Aug. 7, 2024.

(30) Foreign Application Priority Data
Nov. 1, 2023 (KR) 10-2023-0148960
Dec. 27, 2023 (KR) 10-2023-0192199

(51) Int. Cl. H04M 1/02; H01Q 1/24; H01Q 1/38

(52) U.S. Cl. CPC H04M 1/0268; H01Q 1/243; H01Q 1/38; H04M 1/0216; H04M 1/0277

(57) ABSTRACT

A foldable electronic device is provided. The foldable electronic device includes a first housing, a second housing, a first hinge disposed between the first housing and the second housing, a flexible display disposed on the first housing and the second housing, a first hinge cover configured to cover the first hinge, a first flexible printed circuit board disposed between the first hinge and the first hinge cover, and an antenna including a plurality of patch antennas and disposed between the first flexible printed circuit board and the first hinge cover.

### CROSS-REFERENCE TO RELATED APPLICATION(S)

This application is a continuation application, claiming priority under 35 U.S.C. § 365(c), of an International application No. PCT/KR2024/011633, filed on August 7, 2024, which is based on and claims the benefit of a Korean patent application number 10-2023-0148960, filed on November 1, 2023, in the Ministry of Intellectual Property (MOIP), and of a Korean patent application number 10-2023-0192199, filed on December 27, 2023, in the Ministry of Intellectual Property (MOIP), the disclosure of each of which is incorporated by reference herein in its entirety.

### BACKGROUND

### 1. Field

The disclosure relates to a foldable electronic device including an antenna module.

### 2. Description of Related Art

Use of foldable electronic devices that are folded and unfolded in a horizontal direction or a vertical direction is increasing.

The foldable electronic device may operate in a folded state or an unfolded state, with a first housing and a second housing configured to move around a hinge module.

The foldable electronic device may operate in an in-folding and/or out-folding manner by rotating the first housing and the second housing using the hinge module.

The above information is presented as background information only to assist with an understanding of the disclosure. No determination has been made, and no assertion is made, as to whether any of the above might be applicable as prior art with regard to the disclosure.

### SUMMARY

The user demand for expansion of displays of foldable electronic devices is increasing. The foldable electronic device may be implemented in the form of a multi-foldable electronic device including a first housing, a second housing, and a third housing.

In the multi-foldable electronic device, the first housing, the second housing, and the third housing may operate in an in-folding manner and/or an out-folding manner by using a first hinge module and a second hinge module.

The multi-foldable electronic device may include a flexible display that is disposed across at least a portion of the first housing, the second housing, and the third housing.

The multi-foldable electronic device may include at least one antenna module to perform long-range communication and/or short-range communication with another electronic device. For example, the multi-foldable electronic device may perform 5th generation (5G) communication (e.g., millimeter wave (mmWave) communication) by using the at least one antenna module.

The multi-foldable electronic device may be limited in space for disposing the antenna module. For example, when an antenna module is disposed at an outer side (e.g., an edge) of the second housing, and the first housing, the second housing, and the third housing are folded in the in-folding manner, radiation performance of the antenna module disposed in the second housing may be degraded due to a portion of the first housing, the second hinge module, a portion of the third housing, and a conductive portion included in the flexible display.

Aspects of the disclosure are to address at least the above-mentioned problems and/or disadvantages and to provide at least the advantages described below. Accordingly, an aspect of the disclosure is to provide a foldable electronic device including a first hinge module coupled between the first housing and the second housing, and an antenna module disposed between the first hinge module and a first hinge cover configured to cover the first hinge module.

Additional aspects will be set forth in part in the description which follows and, in part, will be apparent from the description, or may be learned by practice of the presented embodiments.

In accordance with an aspect of the disclosure, a foldable electronic device is provided. The foldable electronic device includes a first housing, a second housing, a first hinge disposed between the first housing and the second housing, a flexible display disposed on the first housing and the second housing, a first hinge cover configured to cover the first hinge, a first flexible printed circuit board disposed between the first hinge and the first hinge cover, and an antenna including a plurality of patch antennas and disposed between the first flexible printed circuit board and the first hinge cover.

According to various embodiments of the disclosure, by disposing an antenna module (e.g., a patch array antenna or an mmWave antenna) between a first hinge module coupled between the first housing and the second housing and a first hinge cover configured to cover the first hinge module, degradation of radiation performance of the antenna module is reduced.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment, according to an embodiment of the disclosure;

FIG. 2A is a schematic front view illustrating a foldable electronic device in an unfolded state according to an embodiment of the disclosure;

FIG. 2B is a schematic rear view illustrating the foldable electronic device in the unfolded state according to an embodiment of the disclosure;

FIG. 3 is a view schematically illustrating a state in which a first housing and a third housing of the foldable electronic device are folded according to an embodiment of the disclosure;

FIG. 4 is a view schematically illustrating a state in which the first housing, a second housing, and the third housing of the foldable electronic device are folded according to an embodiment of the disclosure;

FIG. 5 is a schematic rear view of a foldable electronic device in a state in which some components are removed according to an embodiment of the disclosure;

FIG. 6 is a view schematically illustrating a portion of a rear surface of the foldable electronic device according to an embodiment of the disclosure;

FIG. 7 is a cross-sectional view schematically illustrating a portion taken along line A-A′ of FIG. 6 of a foldable electronic device according to an embodiment of the disclosure;

FIG. 8 is a cross-sectional view schematically illustrating a partial configuration of a portion taken along line A-A′ of FIG. 6 of a foldable electronic device according to an embodiment of the disclosure;

FIG. 9 is a cross-sectional view schematically illustrating a partial configuration of a portion taken along line A-A' of FIG. 6 of a foldable electronic device according to an embodiment of the disclosure;

FIG. 10 is a cross-sectional view schematically illustrating a partial configuration of a portion taken along line A-A′ of FIG. 6 of a foldable electronic device according to an embodiment of the disclosure;

FIG. 11 is a view schematically illustrating a first radiation region of a first housing of a foldable electronic device according to an embodiment of the disclosure;

FIG. 12 is a view schematically illustrating a second radiation region of a foldable electronic device according to an embodiment of the disclosure; and

FIG. 13 is a cross-sectional view schematically illustrating a partial configuration of a portion taken along line A-A′ of FIG. 6 of a foldable electronic device according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

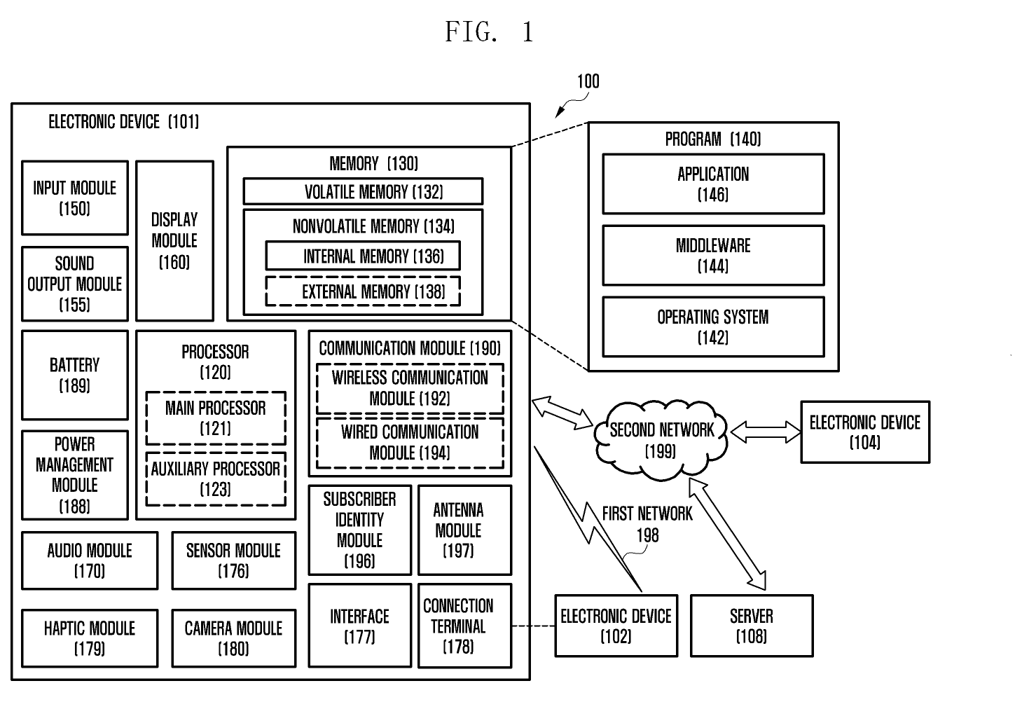

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134 (i.e., internal memory 136 and external memory 138. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. In an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may be configured to store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to another embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to another embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). The connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to another embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as BluetoothTM, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may, for example, identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4th generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to another embodiment, the wireless communication module 192 may support a peak data rate (e.g., 20Gbps or more) for implementing eMBB, loss coverage (e.g., 164dB or less) for implementing mMTC, or user plane (U-plane) latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to some embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

Commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to another embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. As used herein, each of such phrases as "A or B," "at least one of A and B," "at least one of A or B," "A, B, or C," "at least one of A, B, and C," and "at least one of A, B, or C," may include any one of, or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively," as "coupled with," "coupled to," "connected with," or "connected to" another element (e.g., a second element), it denotes that the element may be coupled with the other element directly (e.g., wiredly), wirelessly, or via a third element.

As used in connection with various embodiments of the disclosure, the term "module" may include a unit implemented in hardware, software, or firmware, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

According to various embodiments, each element (e.g., module or program) of the above-described elements may include a single entity or multiple entities, and some of the multiple entities may be separately disposed in another element. According to other embodiments, one or more of the above-described elements or operations may be omitted, or one or more other elements or operations may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

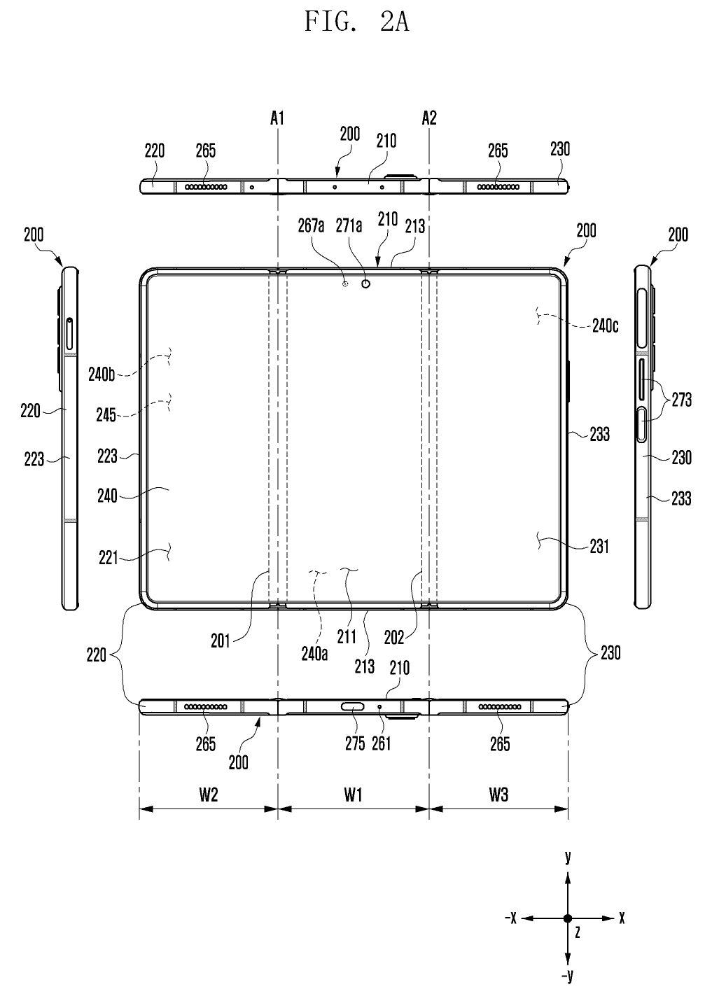

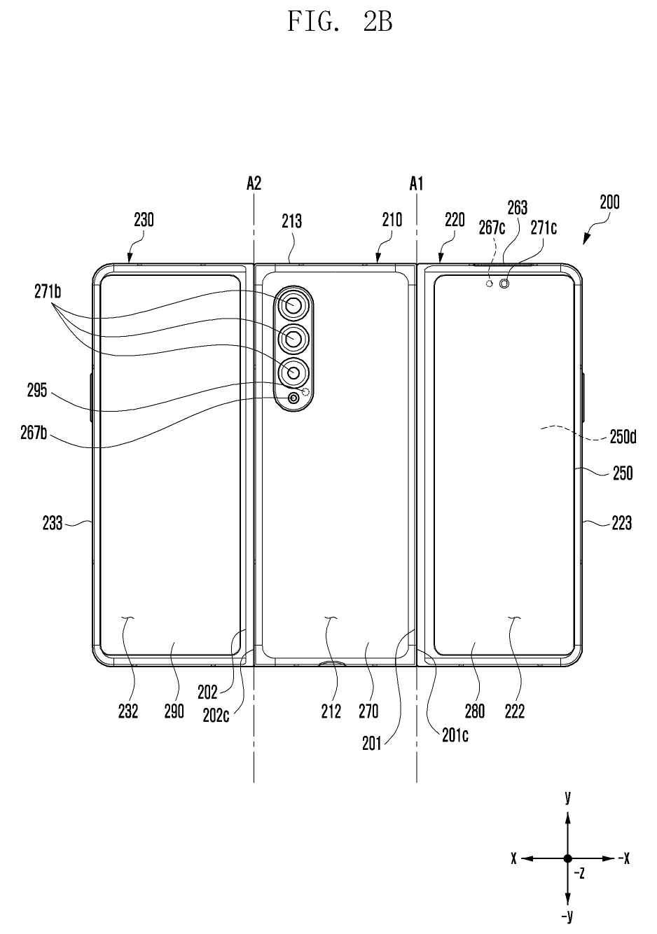

FIG. 2A is a schematic front view illustrating a foldable electronic device in an unfolded state according to an embodiment of the disclosure. FIG. 2B is a schematic rear view illustrating the foldable electronic device in the unfolded state according to an embodiment of the disclosure.

According to various embodiments, embodiments of the electronic device 101 illustrated in FIG. 1 may be included in embodiments of a foldable electronic device 200 (e.g., a multi-foldable electronic device) illustrated in FIGS. 2A and 2B. For example, the foldable electronic device 200 illustrated in FIGS. 2A and 2B may include the processor 120, the memory 130, the input module 150, the sound output module 155, the display module 160, the audio module 170, the sensor module 176, the interface 177, the connection terminal 178, the haptic module 179, the camera module 180, the antenna module 197, and/or the subscriber identification module 196 illustrated in FIG. 1.

Referring to FIGS. 2A and 2B, the foldable electronic device 200 (e.g., a multi-foldable electronic device) according to an embodiment of the disclosure may include a first housing 210, a second housing 220, a third housing 230, a first hinge module 201, a second hinge module 202, and/or a flexible display 240.

According to an embodiment, the first housing 210 may be disposed between the second housing 220 and the third housing 230. The second housing 220 may be foldably and unfoldably coupled to a first side (e.g., in the -x-axis direction) of the first housing 210. The third housing 230 may be foldably and unfoldably coupled to a second side (e.g., in the x-axis direction) of the first housing 210. For example, the first housing 210 may have the first side (e.g., in the -x-axis direction) operationally coupled to at least a portion of the second housing 220 via the first hinge module 201 and the second side (e.g., in the x-axis direction) operationally coupled to at least a portion of the third housing 230 via the second hinge module 202.

The second housing 220 may be foldably coupled to the first side (e.g., in the -x-axis direction) of the first housing 210. The first hinge module 201 may be foldably coupled between the first housing 210 and the second housing 220. The first hinge module 201 may be disposed such that the first housing 210 and the second housing 220 are foldable or unfoldable with respect to each other. The first hinge module 201 may include a hinge device, a hinge member, a hinge plate, or a hinge assembly. The first housing 210 and the second housing 220 may be coupled to each other to be rotatable about a first folding axis A1 by using the first hinge module 201.

According to another embodiment, the first hinge module 201 may be covered by a first hinge cover 201c (e.g., a first hinge housing). The first hinge cover 201c may be configured to cover the first hinge module 201. The first hinge cover 201c may be disposed between the first housing 210 and the second housing 220. The first hinge cover 201c may cover the first hinge module 201 so that the first hinge module 201 is not visible from the outside. The first hinge cover 201c may be at least partially concealed by the first housing 210 and the second housing 220, or may be visually exposed to the outside, depending on whether the first housing 210 and the second housing 220 are in the unfolded state or the folded state. For example, when the first housing 210 and the second housing 220 are in the unfolded state, at least a portion of the first hinge cover 201c may be concealed by the first housing 210 and the second housing 220 and may not be substantially exposed.

According to an embodiment, the third housing 230 may be foldably coupled to the second side (e.g., in the x-axis direction) of the first housing 210. The second hinge module 202 may be foldably coupled between the first housing 210 and the third housing 230. The second hinge module 202 may be disposed such that the first housing 210 and the third housing 230 are foldable or unfoldable with respect to each other. The second hinge module 202 may include a hinge device, a hinge member, a hinge plate, or a hinge assembly. The first housing 210 and the third housing 230 may be coupled to each other to be rotatable about a second folding axis A2 by using the second hinge module 202.

The second hinge module 202 may be covered by a second hinge cover 202c (e.g., a second hinge housing). The second hinge cover 202c may be configured to cover the second hinge module 202. The second hinge cover 202c may be disposed between the first housing 210 and the third housing 230. The second hinge cover 202c may cover the second hinge module 202 so that the second hinge module 202 is not visible from the outside. The second hinge cover 202c may be at least partially concealed by the first housing 210 and the third housing 230, or may be visually exposed to the outside, depending on whether the first housing 210 and the third housing 230 are in the unfolded state or the folded state. For example, when the first housing 210 and the third housing 230 are in the unfolded state, the second hinge cover 202c may be partially concealed by the first housing 210 and the third housing 230 or may be partially exposed.

The foldable electronic device 200 (e.g., a multi-foldable electronic device) may be configured such that the third housing 230 is folded first with respect to the first housing 210 through the second hinge module 202, and the second housing 220 is folded later with respect to the first housing 210 through the first hinge module 201. For example, the third housing 230 may be folded onto the first housing 210 in an in-folding manner about the second hinge module 202. For example, the third housing 230 may be folded onto the first housing 210 while rotating about the second hinge module 202 to be oriented in the z-axis direction and subsequently in the -x-axis direction. For example, the second housing 220 may be folded onto the first housing 210 in an in-folding manner about the first hinge module 201. For example, the second housing 220 may be folded onto the first housing 210 while rotating about the first hinge module 201 to be oriented in the z-axis direction and subsequently in the x-axis direction.

According to an embodiment, the width W3 of the third housing 230 in the horizontal direction (e.g., the x-axis direction and the -x-axis direction) may be smaller than the width W1 of the first housing 210 in the horizontal direction (e.g., the x-axis direction and the -x-axis direction). The width W1 of the first housing 210 in the horizontal direction (e.g., the x-axis direction and the -x-axis direction) may be substantially the same as the width W2 of the second housing 220 in the horizontal direction (e.g., the x-axis direction and the -x-axis direction). According to various embodiments, the width W2 of the second housing 220 in the horizontal direction (e.g., in the x-axis and the -x-axis directions) may be configured to be greater than the width W1 of the first housing 210 in the horizontal direction (e.g., in the x-axis and the -x-axis directions).

The first housing 210 and the third housing 230 may be disposed on opposite sides of the second folding axis A2 on which the second hinge module 202 is disposed, and may have an asymmetric shape with respect to the second folding axis A2. According to various embodiments, the first housing 210 and the third housing 230 may have a symmetric shape with respect to the second folding axis A2. The first housing 210 and the third housing 230 may have different angles or distances from each other depending on whether the foldable electronic device 200 is in the unfolded state, the folded state, or the intermediate state.

According to an embodiment, the first housing 210 and the second housing 220 may be disposed on opposite sides of the first folding axis A1 on which the first hinge module 201 is disposed and may have a substantially symmetric shape with respect to the first folding axis A1. According to various embodiments, the first housing 210 and the second housing 220 may have an asymmetric shape with respect to the first folding axis A1. The first housing 210 and the second housing 220 may have different angles or distances from each other depending on whether the foldable electronic device 200 is in the unfolded state, the folded state, or the intermediate state.

According to another embodiment, the width of the first hinge module 201 may be configured to be greater than the width of the second hinge module 202. For example, when the third housing 230 is folded first relative to the first housing 210 and the second housing 220 is folded relative to the first housing 210 such that the second housing 220 is disposed on the third housing 230, the width of the first hinge module 201 may be configured to be greater than the width of the second hinge module 202. For example, the first hinge module 201 may be a first in-folding hinge, a wide hinge, or a big hinge having a greater width than the second hinge module 202. For example, the second hinge module 202 may be a second in-folding hinge, a slim hinge, or a small hinge having a smaller width than the first hinge module 201. In an embodiment, the first hinge module 201 may have a larger radius of curvature than the second hinge module 202. The second hinge module 202 may have a smaller radius of curvature than that of the first hinge module 201. In an embodiment, although the width of the first hinge module 201 has been described as being greater than the width of the second hinge module 202, the disclosure is not limited thereto, and depending on the type and/or operation of the foldable electronic device 200, the width of the second hinge module 202 may be greater than the width of the first hinge module 201.

According to an embodiment, the flexible display 240 may be disposed on the first housing 210, the second housing 220, and the third housing 230. For example, the flexible display 240 may be disposed to extend across at least a portion of front surfaces (e.g., oriented in the z-axis direction) of the first housing 210, the second housing 220, and the third housing 230. The flexible display 240 may be a first display, a foldable display, or a main display. According to various embodiments, a sub-display 250 may be disposed on a rear surface (e.g., in the -z-axis direction) of the second housing 220. The sub-display 250 may be a second display or an auxiliary display.

Herein, a surface on which the flexible display 240 is disposed may be defined as a front surface (e.g., in the z-axis direction) of the foldable electronic device 200, and the surface opposite to the front surface may be defined as a rear surface (e.g., in the -z-axis direction) of the foldable electronic device 200. A surface surrounding a space between the front surface (e.g., in the z-axis direction) and the rear surface (e.g., in the -z-axis direction) may be defined as a side surface of the foldable electronic device 200.

The flexible display 240 may include a first display region 240a disposed on the first housing 210, a second display region 240b disposed on the second housing 220, and a third display region 240c disposed on the third housing 230 (e.g., the front surface). The first display region 240a, the second display region 240b, and the third display region 240c may be formed integrally to constitute the flexible display 240. According to some embodiments, when the foldable electronic device 200 is in the unfolded state, the flexible display 240 may be configured to be disposed over most of the front surface (e.g., in the z-axis direction) of the foldable electronic device 200. At least a portion of the flexible display 240 may be deformed into a flat shape or a curved shape. The division of the flexible display 240 into the first display region 240a, the second display region 240b, and the third display region 240c may be a physical division. The flexible display 240 may be formed as an overall seamless single screen. According to an embodiment, the sub-display 250 may include a fourth display region 250d. For example, the sub-display 250 may be disposed on the rear surface (e.g., in the -z-axis direction) of the second housing 220.

According to an embodiment, when the foldable electronic device 200 is in the unfolded state, the first housing 210 may include a first surface 211 connected to at least a portion of the first hinge module 201 and the second hinge module 202 and disposed to face the front (e.g., in the z-axis direction) of the foldable electronic device 200, a second surface 212 disposed to face away from the first surface 211, and/or a first side surface member 213 surrounding at least a portion of a first space between the first surface 211 and the second surface 212.

According to an embodiment, when the foldable electronic device 200 is in the unfolded state, the second housing 220 may include a third surface 221 connected to at least a portion of the first hinge module 201 and disposed to face the front (e.g., in the z-axis direction) of the foldable electronic device 200, a fourth surface 222 disposed to face away from the third surface 221, and/or a second side surface member 223 surrounding at least a portion of a second space between the third surface 221 and the fourth surface 222.

When the foldable electronic device 200 is in the unfolded state, the third housing 230 may include a fifth surface 231 connected to at least a portion of the second hinge module 202 and disposed to face the front (e.g., in the z-axis direction) of the foldable electronic device 200, a sixth surface 232 disposed to face away from the fifth surface 231, and/or a third side surface member 233 surrounding at least a portion of the third space between the fifth surface 231 and the sixth surface 232.

According to various embodiments, when the foldable electronic device 200 is in the unfolded state, the first surface 211, the third surface 221, and the fifth surface 231 may be oriented in substantially the same direction (e.g., the z-axis direction). When the foldable electronic device 200 is in the unfolded state, the second surface 212, the fourth surface 222, and the sixth surface 232 may be oriented in substantially the same direction (e.g., the -z-axis direction).

According to various embodiments, when the first housing 210 and the third housing 230 of the foldable electronic device 200 are in the folded state, the first surface 211 and the fifth surface 231 may be disposed to face each other. When the second housing 220 is in the folded state with respect to the first housing 210 of the foldable electronic device 200, and the second housing 220 is disposed above the third housing 230 (e.g., in the z-axis direction), the third surface 221 of the second housing 220 and the sixth surface 232 of the third housing 230 may be disposed to face each other.

According to various embodiments, the foldable electronic device 200 may include a recess 245 formed to accommodate the flexible display 240 through structural coupling of the first housing 210, the second housing 220, and the third housing 230. The recess 245 may have substantially the same size as the flexible display 240.

When the foldable electronic device 200 is in the unfolded state, the first housing 210, the second housing 220, and the third housing 230 may form an angle of about 180 degrees, and the first display region 240a, the second display region 240b, and the third display region 240c of the flexible display 240 may be disposed to be oriented in substantially the same direction (e.g., the z-axis direction) while forming substantially the same plane. The fourth display region 250d of the sub-display 250 may be disposed to face a direction opposite to the third display region 240c.

According to other embodiments, the first housing 210 and the second housing 220 may form an angle that allows the first and second housings to be stopped at a predetermined folding angle between the folded state and the unfolded state using the first hinge module 201 (e.g., free-stop function). In various embodiments, the second housing 220 may be rotated to move toward the second surface 212 (e.g., the rear surface) of the first housing 210 while being biased in an unfolding direction (e.g., the -z-axis direction) based on a predetermined inflection angle by using the first hinge module 201.

According to various embodiments, the first housing 210 and the third housing 230 may form an angle that allows the first and third housings to be stopped at a predetermined folding angle between the folded state and the unfolded state by using the second hinge module 202. In various embodiments, the third housing 230 may be rotated to move toward the second surface 212 (e.g., a rear surface) of the first housing 210 while being biased in the unfolding direction (e.g., the -z-axis direction) based on a predetermined inflection angle by using the second hinge module 202.

The flexible display 240 may be disposed to be supported by the first surface 211 of the first housing 210, the first hinge module 201, the third surface 221 of the second housing 220, the second hinge module 202, and the fifth surface 231 of the third housing 230. In an embodiment, the sub-display 250 (e.g., the fourth display region 250d) may be disposed such that the sub-display 250 is at least partially visible from the outside through the fourth surface 222 in an inner space of the third housing 220. In various embodiments, the sub-display 250 may be disposed in the internal space of the third housing 230 to be visible from the outside through the sixth surface 232.

According to an embodiment, the flexible display 240 may be mainly used when the foldable electronic device 200 is in the unfolded state, and the sub-display 250 may be mainly used when the foldable electronic device 200 is in the folded state.

According to another embodiment, the foldable electronic device 200 may include a first rear surface cover 270 disposed on the second surface 212 of the first housing 210, a second rear surface cover 280 disposed on the fourth surface 222 of the second housing 220, and/or a third rear surface cover 290 disposed on the sixth surface 232 of the third housing 230. In various embodiments, at least a portion of the first rear surface cover 270 may be integrally formed with a portion of the first side surface member 213. According to various embodiments, at least a portion of the second rear surface cover 280 may be integrated with a portion of the second side surface member 223. According to various embodiments, at least a portion of the third rear surface cover 290 may be integrated with a portion of the third side surface member 233. According to an embodiment, at least one of the first rear surface cover 270, the second rear surface cover 280, and the third rear surface cover 290 may be made of a substantially transparent plate (e.g., a glass plate including various coating layers, or a polymer plate) or an opaque plate.

The first rear surface cover 270 may be made of, for example, coated or colored glass, ceramic, polymer, metal (e.g., aluminum, stainless steel (STS), or magnesium), or an opaque plate such as a combination of two or more of these materials. According to various embodiments, the second rear surface cover 280 may be formed of a substantially transparent plate of, for example, glass or polymer. According to various embodiments, the third rear surface cover 290 may be formed of coated or colored glass, ceramic, polymer, metal (e.g., aluminum, stainless steel (STS), or magnesium), or an opaque plate such as a combination of two or more of these materials. The sub-display 250 (e.g., the fourth display region 250d) may be disposed to be visible from outside through the second rear surface cover 280 in the inner space of the third housing 220.

According to various embodiments, the foldable electronic device 200 may include at least one of an input module 261, sound output modules 263 and 265, sensor modules 267a, 267b, and 267c, camera modules 271a, 271b, and 271c, key input devices 273, an indicator (not illustrated), or a connector port 275. In various embodiments, at least one of the above-described components may be omitted from the foldable electronic device 200 or at least one other component may be additionally included.

According to an embodiment, the input module 261 may include at least one microphone disposed to detect the direction of sound. The input module 261 may include the input module 150 illustrated in FIG. 1.

The sound output modules 263 and 265 may include at least one speaker. The sound output modules 263 and 265 may include a receiver 263 for a voice call disposed through the fourth surface 222 of the second housing 220, and a speaker 265 disposed on a portion of an upper portion (e.g., in the y-axis direction) and a portion of a lower portion (e.g., in the -y-axis direction) of the second side surface member 223 of the second housing 220, and/or on a portion of an upper portion (e.g., in the y-axis direction) and a portion of a lower portion (e.g., in the -y-axis direction) of the third side surface member 233 of the third housing 220. The sound output modules 263 and 265 may include the sound output module 155 illustrated in FIG. 1.

According to an embodiment, the input module 261, the sound output modules 263 and 265, and the connector port 275 may be disposed in the space of the first housing 210, the second housing 220, and/or the third housing 230, and may be exposed to the external environment through one or more holes provided in the first housing 210, the second housing 220, and/or the third housing 230. In an embodiment, the holes provided in the first housing 210, the second housing 220, and/or the third housing 230 may be commonly used for the input module 261 and the sound output modules 263 and 265. In an embodiment, the sound output modules 263 and 265 may include a speaker that operates without holes formed in the second housing 220 and/or the third housing 230 (e.g., a piezo speaker).

According to various embodiments, the camera modules 271a, 271b, and 271c may include a first camera module 271a disposed on the first surface 211 of the first housing 210, a second camera module 271b disposed on the second surface 212 of the first housing 210, and/or a third camera module 271c disposed on the fourth surface 222 of the second housing 220. According to an embodiment, the foldable electronic device 200 may include a flash 295 disposed near the second camera module 271b. The flash 295 may include, for example, a light-emitting diode or a xenon lamp. The camera modules 271a, 271b, and 271c may include one or more lenses, an image sensor, and/or an image signal processor. In an embodiment, at least one of the camera modules 271a, 271b, and 271c may include two or more lenses (e.g., wide-angle and telephoto lenses) and image sensors, and the camera modules may be disposed together on one surface of the first housing 210, the second housing 220, and/or the third housing 230. For example, the camera modules 271a, 271b, and 271c may include the camera module 180 illustrated in FIG. 1.

According to an embodiment, the sensor modules 267a, 267b, and 267c may generate electrical signals or data values corresponding to an internal operating state or an external environmental state of the foldable electronic device 200. According to various embodiments, the sensor modules 267a, 267b, and 267c may include a first sensor module 267a disposed on the first surface 211 of the first housing 210, a second sensor module 267b disposed on the second surface 212 of the first housing 210, and/or a third sensor module 267c disposed on the fourth surface 222 of the second housing 220. For example, the sensor modules 267a, 267b, and 267c may include the sensor module 176 illustrated in FIG. 1.

According to various embodiments, the foldable electronic device 200 may further include an unillustrated sensor module, for example, at least one of a 6-axis sensor (e.g., an acceleration sensor and a gyro sensor), an angle detection sensor, a Hall sensor, an angular velocity sensor, a folding and unfolding detection sensor, a proximity sensor, a pressure sensor, a magnetic sensor, a biometric sensor, a temperature sensor, a humidity sensor, a gesture sensor, a grip sensor, a color sensor, an infrared (IR) sensor, an illuminance sensor, an ultrasonic sensor, an iris recognition sensor, a distance detection sensor (e.g., a time of flight (TOF) sensor or a light detection and ranging (LiDAR) sensor), and a fingerprint recognition sensor.

According to another embodiment, key input devices 273 may be disposed to be exposed to the outside through the third side surface member 233 of the third housing 230. In an embodiment, the key input device 273 may be disposed to be exposed to the outside through the second side surface member 223 of the second housing 220. In an embodiment, the foldable electronic device 200 may not include some or all of the key input devices 273, and the key input devices 273 not included may be implemented in another form such as soft keys on the flexible display 240 and/or the sub-display 250. In various embodiments, the key input devices 273 may be implemented using a pressure sensor and/or a touch sensor included in the flexible display 240 and/or the sub-display 250. In an embodiment, the key input devices 273 may include a power button and/or a volume control button of the foldable electronic device 200.

According to an embodiment, the connector port 275 may include a connector (e.g., a USB connector or an interface connector port module (IF module)) for transmitting and/or receiving power and/or data with an external electronic device (e.g., the external electronic devices 102, 104, and 108 of FIG. 1). In an embodiment, the connector port 275 may be configured to perform a function for transmitting/receiving an audio signal to and from the external electronic device, or may further include a separate connector port (e.g., an ear jack hole) configured to perform an audio signal transmitting/receiving function. For example, the connector port 275 may be formed in a portion of the first side surface member 213 of the first housing 210. For example, the connector port 275 may include the connection terminal 178 illustrated in FIG. 1.

At least one camera module 271a or 271c among the camera modules 271a, 271b, and 271c, at least one sensor module 267a or 267c among the sensor modules 267a, 267b, and 267c, and/or an indicator may be arranged to be exposed through at least one of the displays 240 and 250. For example, at least one camera module 271a or 271c, at least one sensor module 267a or 267c, and/or an indicator may be disposed inside at least one of the housings 210, 220, and 230, under an active region (display region) of at least one of the displays 240 and 250, and may be arranged to be exposed to an external environment through a transparent region or an opening perforated up to a cover member (e.g., a window layer (not illustrated) of the flexible display 240 and/or the second rear surface cover 280).

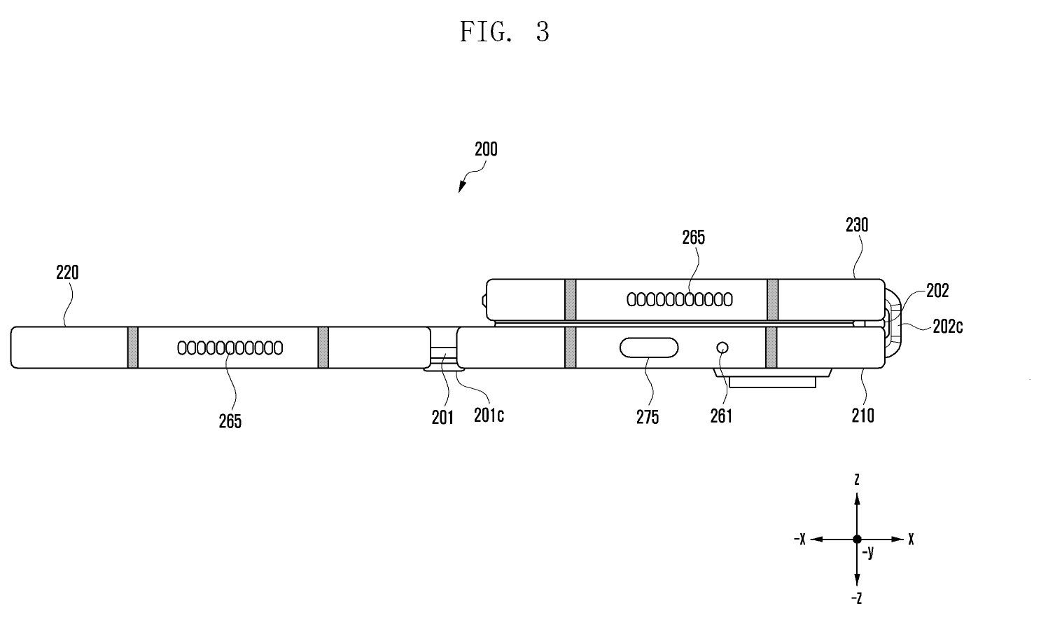

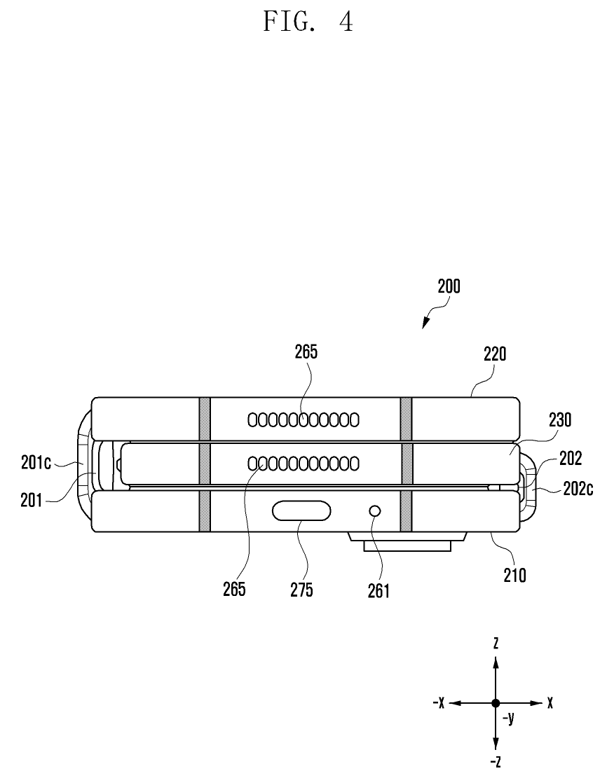

FIG. 3 is a view schematically illustrating a state in which the first housing and the third housing of the foldable electronic device are folded according to an embodiment of the disclosure. FIG. 4 is a view schematically illustrating a state in which the first housing, the second housing, and the third housing of the foldable electronic device are folded according to an embodiment of the disclosure.

According to an embodiment, FIG. 3 may be a view illustrating a state in which the third housing 230 of the foldable electronic device 200 (e.g., a multi-foldable electronic device) is folded toward the first housing 210 and the first housing 210 and the second housing 220 are unfolded, as viewed in the -y-axis direction. According to an embodiment, FIG. 4 may be a view illustrating a state in which the third housing 230 of the foldable electronic device 200 is first folded toward the first housing 210, and the second housing 220 is later folded toward the first housing 210 so that the second housing 220 is disposed above the third housing 230 (e.g., in the z-axis direction), as viewed in the -y-axis direction. For example, the foldable electronic device 200 illustrated in FIGS. 3 and 4 may include a multi-foldable electronic device folded in a G-type configuration. According to various embodiments, the foldable electronic device 200 may be folded not only in the G-type shape but also in various configurations such as a Z-type configuration.

Referring to FIGS. 3 and 4, the foldable electronic device 200 (e.g., a multi-foldable electronic device) may include a first housing 210, a second housing 220, a third housing 230, a first hinge module 201, a first hinge cover 201c, a second hinge module 202, and/or a second hinge cover 202c.

According to an embodiment, the third housing 230 may be first folded onto the first housing 210 (e.g., in the z-axis direction) about the second hinge module 202 (e.g., a second in-folding hinge).

According to an embodiment, after the third housing 230 is folded onto the first housing 210 about the second hinge module 202, the second housing 220 may be folded toward the first housing 210 about the first hinge module 201 (e.g., a first in-folding hinge) so as to be disposed above the third housing 230 (e.g., in the z-axis direction).

The first hinge module 201 may have a first width. The second hinge module 202 may have a second width. For example, the first width may be greater than the second width. According to various embodiments, since the third housing 230 is first folded relative to the first housing 210 and the second housing 220 is later folded relative to the first housing 210 so as to be disposed above the third housing 230 (e.g., in the z-axis direction), the first width of the first hinge module 201 may be configured to be greater than the second width of the second hinge module 202. For example, the first hinge module 201 may include a first folding hinge, a slim hinge, or a small hinge, which has a greater width than the second hinge module 202. For example, the second hinge module 202 may be a second in-folding hinge, a wide hinge, or a big hinge having a smaller width than the first hinge module 201. In an embodiment, the first hinge module 201 may have a larger radius of curvature than the second hinge module 202. The second hinge module 202 may have a smaller radius of curvature than the first hinge module 201.

According to another embodiment, the first hinge cover 201c (e.g., a first hinge housing) may be disposed between the first housing 210 and the second housing 220. The first hinge cover 201c may be disposed to cover at least a portion of the first hinge module 201. The first hinge cover 201c may be at least partially concealed by the first housing 210 and the second housing 220, or may be visually exposed to the outside, depending on whether the first housing 210 and the second housing 220 are in the unfolded state or the folded state. For example, when the first housing 210 and the second housing 220 are in the unfolded state, at least a portion of the first hinge cover 201c may be concealed by the first housing 210 and the second housing 220 and may not be substantially exposed. For example, when the first housing 210 and the second housing 220 are in the folded state, at least a portion of the first hinge cover 201c may be visually exposed to the outside between the first housing 210 and the second housing 220. The first hinge cover 201c may include at least a partially curved surface. The first hinge cover 201c may be formed of a conductive material (e.g., metal) and/or a non-conductive material (e.g., polymer).

According to still another embodiment, the second hinge cover 202c (e.g., a second hinge housing) may be disposed between the first housing 210 and the third housing 230. The second hinge cover 202c may be disposed to cover at least a portion of the second hinge module 202. The second hinge cover 202c may be partially concealed by at least a portion of the first housing 210 and the third housing 230, or may be partially exposed, depending on whether the first housing 210 and the third housing 230 are in the unfolded state or the folded state. For example, when the first housing 210 and the third housing 230 are in the unfolded state, the second hinge cover 202c may be partially concealed by the first housing 210 and the third housing 230 or may be partially exposed. For example, when the first housing 210 and the third housing 230 are in the folded state, at least a portion of the second hinge cover 202c may be visually exposed to the outside between the first housing 210 and the third housing 230. The second hinge cover 202c may include at least a partially curved surface. The second hinge cover 202c may be formed of a conductive material (e.g., metal) and/or a non-conductive material (e.g., polymer).

According to various embodiments, the width of the first hinge cover 201c may be greater than the width of the second hinge cover 202c. For example, since the first width of the first hinge module 201 is greater than the second width of the second hinge module 202, the width of the first hinge cover 201c may be formed to be greater than the width of the second hinge cover 202c.

According to various embodiments, the foldable electronic device 200 (e.g., a multi-foldable electronic device) disclosed below may include at least some of the embodiments described with reference to FIGS. 1, 2A, 2B, 3, and 4. Embodiments related to the foldable electronic device 200 disclosed below may, for example, be integrated into and applied to the embodiments of the foldable electronic device 200 illustrated in FIGS. 2A, 2B, 3, and 4. In the description of the foldable electronic device 200 according to various embodiments of the disclosure described below, the same reference numerals are assigned to components that are substantially the same as the embodiments described above with reference to FIGS. 1, 2A, 2B, 3, and 4, and redundant descriptions of their functions may be omitted.

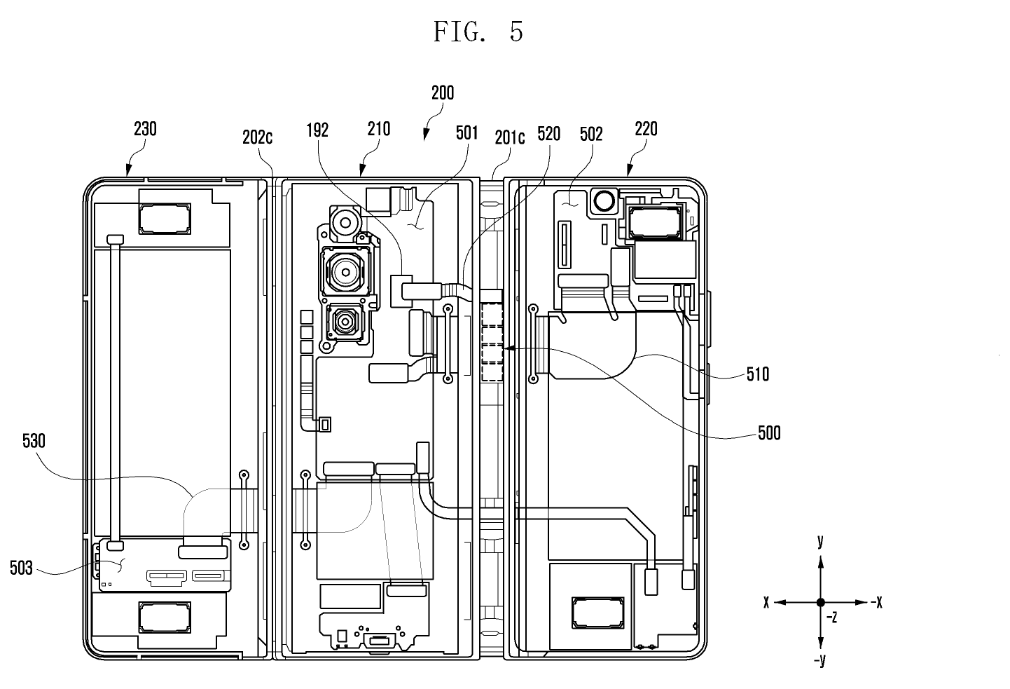

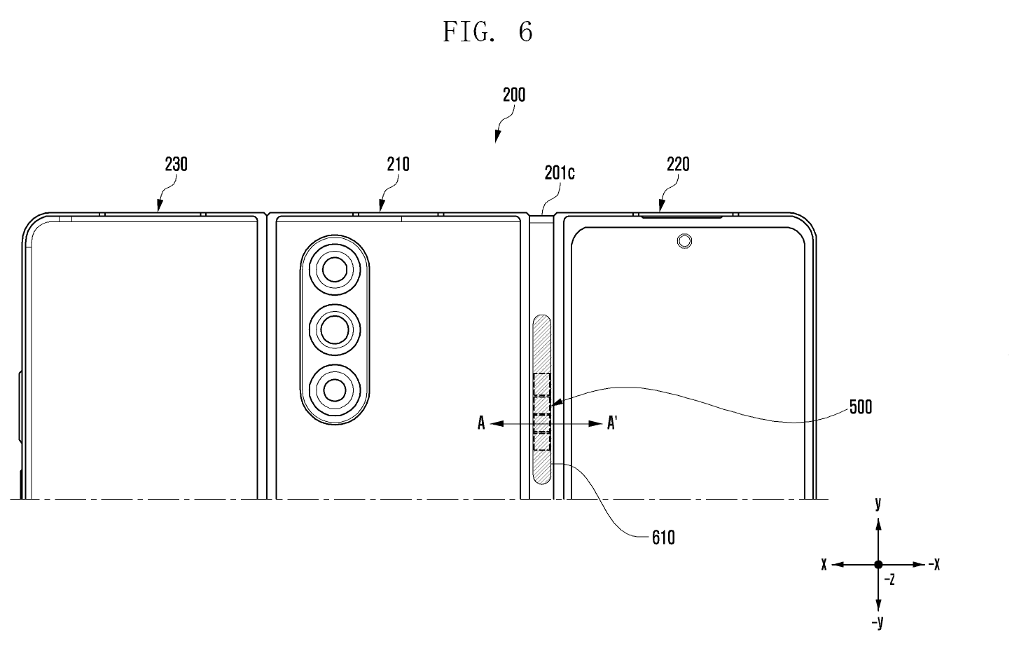

FIG. 5 is a schematic rear view of a foldable electronic device in a state in which some components are removed according to an embodiment of the disclosure. FIG. 6 is a schematic rear view of a portion of the foldable electronic device according to an embodiment of the disclosure.

According to various embodiments, FIG. 5 may be a schematic view illustrating a state in which the first rear surface cover 270, the second rear surface cover 280, and the third rear surface cover 290 are removed from the foldable electronic device 200 illustrated in FIG. 2B according to an embodiment of the disclosure, as viewed from the rear side (e.g., in the -z-axis direction). FIG. 6 may be a schematic view illustrating a configuration of the first hinge cover 201c in a portion of the foldable electronic device 200 illustrated in FIG. 2B according to an embodiment of the disclosure.

According to an embodiment, the foldable electronic device 200 may include a first housing 210, a second housing 220, and a third housing 230.

The first housing 210 may include a first printed circuit board 501. The second housing 220 may include a second printed circuit board 502. The third housing 230 may include a third printed circuit board 503.

According to an embodiment, the first printed circuit board 501 and the second printed circuit board 502 may be electrically connected to each other using a first flexible printed circuit board (FPCB) 510 (e.g., a first conductive connection member). The first flexible printed circuit board 510 may be disposed to partially extend across the first housing 210 and the second housing 220. For example, the first flexible printed circuit board 510 may be disposed between the first housing 210 and the second housing 220 while extending across at least a portion of the first hinge cover 201c.

According to another embodiment, the first printed circuit board 501 and the third printed circuit board 503 may be electrically connected to each other using a third flexible printed circuit board 530 (e.g., a third conductive connection member). The third flexible printed circuit board 530 may be disposed to partially extend across the first housing 210 and the third housing 230. For example, the third flexible printed circuit board 530 may be disposed between the first housing 210 and the third housing 230 while extending across at least a portion of the second hinge cover 202c.

According to an embodiment, a first hinge cover 201c may be disposed between the first housing 210 and the second housing 220. A second hinge cover 202c may be disposed between the first housing 210 and the third housing 230. An antenna module 500 may be disposed on at least a portion of an inner side (e.g., in the z-axis direction) of the first hinge cover 201c.

According to an embodiment, a first hinge module 201 may be disposed on an inner side (e.g., in the -z-axis direction) of the first hinge cover 201c. A second hinge module 202 may be disposed on an inner side (e.g., in the -z-axis direction) of the second hinge cover 202c. For example, the width of the first hinge module 201 may be configured to be greater than the width of the second hinge module 202. According to various embodiments, the first hinge module 201 having a greater width may be disposed on an inner side (e.g., in the -z-axis direction) of the second hinge cover 202c.

According to another embodiment, the antenna module 500 may include a plurality of patch antennas. The antenna module 500 may include at least one patch array antenna or mmWave antenna. The antenna module 500 may transmit signals or power to the outside (e.g., to an external electronic device, such as the external electronic device 102 or 104 of FIG. 1) or receive signals or power from the outside. The antenna module 500 may include an antenna (e.g., a patch array antenna) including a radiator formed of a conductor or a conductive pattern formed on a substrate (e.g., a printed circuit board). The antenna module 500 may form an mmWave antenna module. The mmWave antenna module may include a printed circuit board, an RFIC disposed on or adjacent to a first surface (e.g., a lower surface) of the printed circuit board and configured to support a predetermined high-frequency band (e.g., an mmWave band), and a plurality of antennas (e.g., array antennas) disposed on or adjacent to a second surface (e.g., an upper surface or a side surface) of the printed circuit board and configured to transmit or receive signals of the predetermined high-frequency band. The antenna module 500 may include the antenna module 197 illustrated in FIG. 1.

The antenna module 500 may be electrically connected to a wireless communication module 192 (e.g., an RFIC) disposed on the first printed circuit board 501 using the second flexible printed circuit board 520 (e.g., a second conductive connection member). According to various embodiments, the antenna module 500 may be electrically connected to a processor (e.g., the processor 120 of FIG. 1) disposed on the first printed circuit board 501 using the second flexible printed circuit board 520. For example, the antenna module 500 may transmit and receive wireless signals using a frequency band ranging from about 3 GHz to about 300 GHz.

Referring to FIG. 6, the first hinge cover 201c may include a non-conductive portion 610 in at least a portion thereof. The non-conductive portion 610 may be partially formed in the first hinge cover 201c. The non-conductive portion 610 may include a non-conductive injection-molded member formed of a polymer material. The non-conductive portion 610 may be disposed to overlap the antenna module 500. For example, the antenna module 500 may be disposed at a position overlapping the non-conductive portion 610. For example, the non-conductive portion 610 may be formed at a position corresponding to the antenna module 500. The non-conductive portion 610 may be formed for radiation of wireless signals from the antenna module 500. For example, the non-conductive portion 610 may include a radiation region of the antenna module 500. According to various embodiments, portions of the first hinge cover 501c other than the non-conductive portion 610 may be formed of a conductive material (e.g., metal).

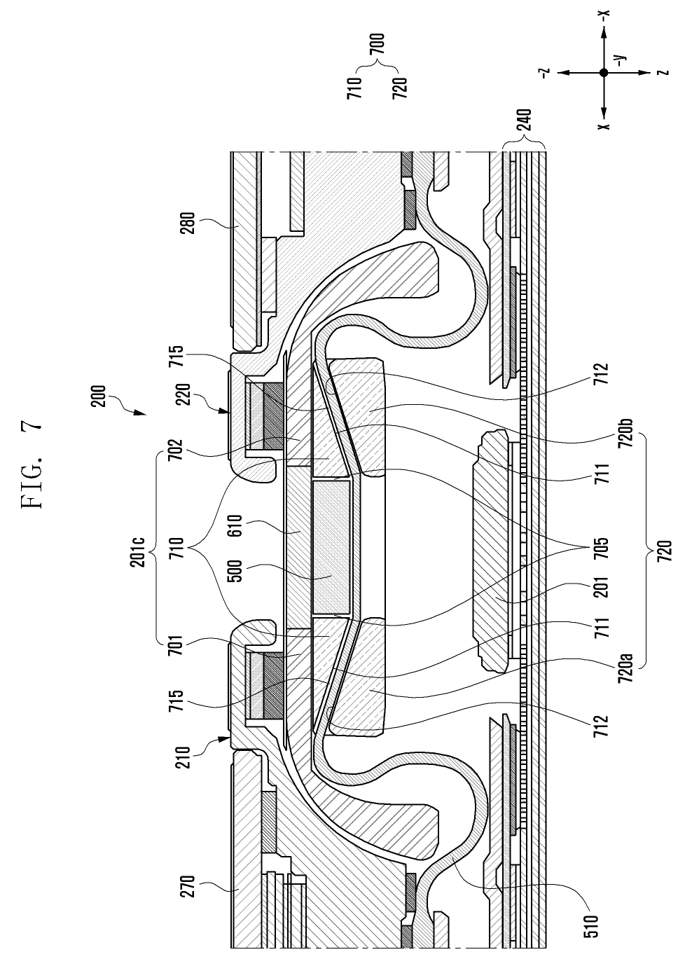

FIG. 7 is a cross-sectional view schematically illustrating a portion of a foldable electronic device, taken along line A-A′ of FIG. 6, according to an embodiment of the disclosure.

According to various embodiments, FIG. 7 may be a schematic view illustrating a cross-sectional view of a portion of the first housing 210, the first hinge cover 201c, and a portion of the second housing 220 taken along line A-A' of FIG. 6 of the foldable electronic device 200 (e.g., a multi-foldable electronic device), as viewed in the -y-axis direction.

Referring to FIG. 7, the first hinge cover 201c (e.g., a first hinge housing) may be disposed between the first housing 210 and the second housing 220. The first hinge cover 201c may be disposed to cover the first hinge module 201. The first hinge cover 201c may be disposed to cover at least a portion of the first hinge module 201. The first hinge cover 201c may include a non-conductive portion 610 in at least a portion thereof. The non-conductive portion 610 may be partially formed in the first hinge cover 201c. For example, when the first housing 210 and the second housing 220 are in the unfolded state via the first hinge module 201, the non-conductive portion 610 may be formed in a region where the first hinge cover 201c is partially exposed to the outside of the foldable electronic device 200. For example, the non-conductive portion 610 may be formed in a central region of the first hinge cover 201c. For example, the non-conductive portion 610 may be formed between a first portion 701 (e.g., in the x-axis direction) and a second portion 702 (e.g., in the -x-axis direction) of the first hinge cover 201c.

According to an embodiment, the foldable electronic device 200 may include a guide structure 700, an antenna module 500, and a first flexible printed circuit board 510. For example, at least a portion of the guide structure 700, the antenna module 500, and the first flexible printed circuit board 510 may be disposed between the first hinge module 201 and the first hinge cover 201c.

The guide structure 700 may be attached to an inner surface (e.g., in the z-axis direction) of the first hinge cover 201c using, for example, an adhesive. The guide structure 700 may include a first part 710 and a second part 720. At least a portion of the first part 710 and the second part 720 may be integrally connected. The first part 710 and the second part 720 may be partially spaced apart from each other. For example, the first part 710 and the second part 720 may define a gap 715 formed in the partially spaced region. For example, at least a portion of the first flexible printed circuit board 510 may be disposed in the gap 715. For example, the first part 710 may be disposed in the -z-axis direction with respect to the first flexible printed circuit board 510. The second part 720 may be disposed in the z-axis direction with respect to the first flexible printed circuit board 510.

The first part 710 may be attached to the inner surface (e.g., in the z-axis direction) of the first hinge cover 201c. The guide structure 700 may include an accommodation space 705 configured to accommodate the antenna module 500. For example, the guide structure 700 may include, in the first part 710, an accommodation space 705 configured to accommodate the antenna module 500.

According to an embodiment, the second part 720 may be disposed between the first hinge module 201 and the first hinge cover 201c. The second part 720 may be disposed between the first hinge module 201 and the first flexible printed circuit board 510. At least a portion of the second part 720 may be separated with respect to a placement position of the antenna module 500. For example, at least a portion of the second part 720 may include a first portion 720a and a second portion 720b separated with respect to the placement position of the antenna module 500. For example, the second part 720 may be disposed to be spaced apart from the antenna module 500. For example, the first portion 720a and the second portion 720b of the second part 720 may be disposed to be spaced apart from each other.

According to another embodiment, the guide structure 700 may be configured to guide at least a portion of the first flexible printed circuit board 510 extending across the first hinge cover 201c. For example, the guide structure 700 may guide at least a portion of the first flexible printed circuit board 510 inserted into an interior (e.g., the gap 715) of the first part 710 and the second part 720 so that the first flexible printed circuit board 510 is bent flexibly or gradually without being abruptly bent. For example, the guide structure 700 may guide at least a portion of the first flexible printed circuit board 510 inserted into the interior (e.g., the gap 715) of the first part 710 and the second part 720 to be deformed within a predetermined range.

According to an embodiment, at least a portion of the first part 710 may include a first inclined surface 711. For example, the first part 710 may include a first inclined surface 711 formed in the z-axis direction. For example, at least one first inclined surface 711 may be formed in the z-axis direction of the first part 710. At least a portion of the second part 720 may include a second inclined surface 712. For example, the second part 720 may include a second inclined surface 712 formed in the -z-axis direction. For example, at least one second inclined surface 712 may be formed in the -z-axis direction of the second part 720.

According to another embodiment, the first inclined surface 711 and the second inclined surface 712 may be formed at positions corresponding to each other. The first inclined surface 711 and the second inclined surface 712 may include substantially the same inclination. For example, the first inclined surface 711 and the second inclined surface 712 may allow the first flexible printed circuit board 510 disposed in the gap 715 between the first part 710 and the second part 720 to be bent flexibly or gradually. For example, the first inclined surface 711 and the second inclined surface 712 may allow the first flexible printed circuit board 510 disposed in the gap 715 between the first part 710 and the second part 720 to be partially bent.

According to various embodiments, the guide structure may include a guide member, a guide part, a guide body, or a guide structure. For example, the guide structure may be referred to as a guide member, a guide part, a guide body, or a guide structure.

The antenna module 500 may be attached to the inner surface (e.g., in the z-axis direction) of the first hinge cover 201c using, for example, an adhesive. The antenna module 500 may include a plurality of patch antennas. The antenna module 500 may be disposed in the accommodation space 705 formed in the guide structure 700 (e.g., the first part 710). The antenna module 500 may be disposed between the first flexible printed circuit board 510 and the first hinge cover 201c. The antenna module 500 may be disposed at a position overlapping the non-conductive portion 610.

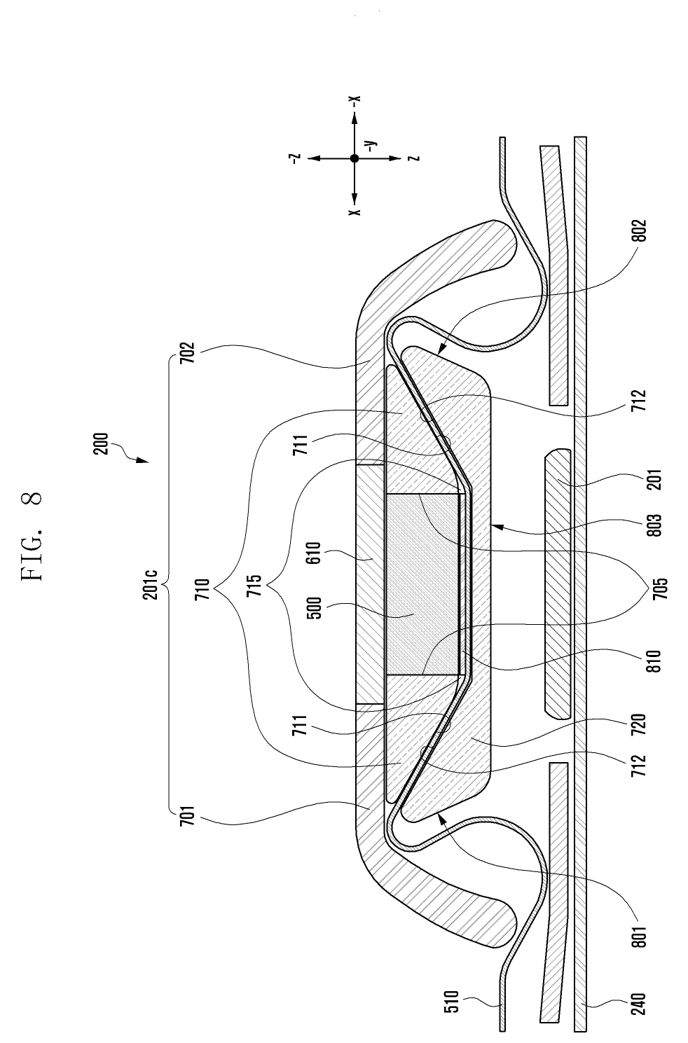

According to an embodiment, the antenna module 500 may be disposed in the accommodation space 705 formed in the guide structure 700 (e.g., the first part 710) and may be supported by the guide structure 700. The first flexible printed circuit board 510 may be partially disposed under the antenna module 500 (e.g., in the z-axis direction). For example, a shielding member (e.g., the shielding member 810 of FIG. 8) may be disposed between the antenna module 500 and the first flexible printed circuit board 510. The shielding member (e.g., the shielding member 810 of FIG. 8) may shield noise generated from the first flexible printed circuit board 510 from being transmitted to the antenna module 500.

At least a portion of the first flexible printed circuit board 510 may be disposed between the first hinge module 201 and the first hinge cover 201c. At least a portion of the first flexible printed circuit board 510 may be disposed in the gap 715 formed between the first part 710 and the second part 720. At least a portion of the first flexible printed circuit board 510 may be disposed between the first part 710 and the first hinge module 201.

FIG. 8 is a cross-sectional view schematically illustrating a partial configuration of a portion taken along line A-A′ of FIG. 6 of a foldable electronic device according to an embodiment of the disclosure.

According to various embodiments, FIG. 8 may be a schematic view illustrating a partial configuration of a cross-sectional view taken along line A-A′ of FIG. 6 of the foldable electronic device 200 (e.g., a multi-foldable electronic device), as viewed in the -y-axis direction. For example, FIG. 8 may be a view schematically illustrating a configuration in which the first housing 210 and the second housing 220 of the foldable electronic device 200 illustrated in FIG. 7 are omitted.

According to various embodiments, the embodiments of the foldable electronic device 200 illustrated in FIG. 7 may be integrated into and applied to the embodiment illustrated in FIG. 8. The embodiments of the foldable electronic device 200 illustrated in FIG. 8 may also be integrated into and applied to the embodiment illustrated in FIG. 7.

Referring to FIG. 8, in the foldable electronic device 200 illustrated in FIG. 8, the second part 720 (e.g., the second part 720 of the guide structure 700 of FIG. 7) may be integrally formed without being separated. In the foldable electronic device 200 illustrated in FIG. 8, a shielding member 810 may be disposed between the antenna module 500 and at least a portion of the first flexible printed circuit board 510.

According to an embodiment, the first hinge cover 201c may be disposed between the first housing 210 and the second housing 220. The first hinge cover 201c may be disposed to cover at least a portion of the first hinge module 201. The first hinge cover 201c may include a non-conductive portion 610 in at least a portion thereof.

According to an embodiment, the foldable electronic device 200 may include the first part 710 and the second part 720 of a guide structure 700, the antenna module 500, the first flexible printed circuit board 510, and/or the shielding member 810. For example, the first part 710 and the second part 720 of the guide structure 700, the antenna module 500, the shielding member 810, and the first flexible printed circuit board 510 may be disposed between the first hinge module 201 and the first hinge cover 201c.

The first part 710 of the guide structure 700 and the antenna module 500 may be coupled to the inner side (e.g., in the z-axis direction) of the first hinge cover 201c using, for example, an adhesive. At least a portion of the first part 710 and the second part 720 may be integrally connected.

According to an embodiment, the antenna module 500 may be disposed in the accommodation space 705 formed in the first part 710. The antenna module 500 may be disposed at a position overlapping the non-conductive portion 610 of the first hinge cover 201c. For example, the antenna module 500 and the non-conductive portion 610 may be partially spaced apart from each other. For example, an air layer may be formed in the partially spaced region between the antenna module 500 and the non-conductive portion 610. For example, the non-conductive portion 610 may include a stepped shape, a step portion, and an inclined surface formed in the partially spaced region. The antenna module 500 may be disposed in the accommodation space 705 formed in the first part 710 and may be configured to be supported by at least a portion of the first part 710. At least a portion of the first flexible printed circuit board 510 may be partially disposed under the antenna module 500 (e.g., in the z-axis direction). The shielding member 810 may be disposed between the antenna module 500 and at least a portion of the first flexible printed circuit board 510. The shielding member 810 may shield noise generated from the first flexible printed circuit board 510 from being transmitted to the antenna module 500.

According to an embodiment, at least a portion of the first part 710 may include a first inclined surface 711. For example, the first part 710 may include at least one first inclined surface 711 formed in the z-axis direction. At least a portion of the second part 720 may include a second inclined surface 712. For example, the second part 720 may include at least one second inclined surface 712 formed in the -z-axis direction. The first inclined surface 711 and the second inclined surface 712 may be formed at positions corresponding to each other. The first inclined surface 711 and the second inclined surface 712 may include substantially the same inclination. For example, the first inclined surface 711 and the second inclined surface 712 may allow the first flexible printed circuit board 510 disposed in the gap 715 between the first part 710 and the second part 720 to be bent flexibly or gradually. For example, the first inclined surface 711 and the second inclined surface 712 may allow the first flexible printed circuit board 510 disposed in the gap 715 between the first part 710 and the second part 720 to be partially bent.

According to an embodiment, the second part 720 may be disposed in the z-axis direction of the first flexible printed circuit board 510. The second part 720 may be partially spaced apart from and partially connected to the first part 710. The first part 710 may support at least a portion of the first flexible printed circuit board 510 disposed thereon (e.g., in the -z-axis direction). The first flexible printed circuit board 510 may be disposed between a portion of the first part 710, the shielding member 810, and the second part 720.

The second part 720 disclosed in FIG. 8 may be integrally formed, unlike the second part 720 disclosed in FIG. 7. For example, unlike the embodiment disclosed in FIG. 7, the second part 720 may not be separated into a first portion 720a and a second portion 720b.

According to another embodiment, the second part 720 may include a first region 801, a second region 802, and a third region 803. For example, the first region 801 may correspond to a portion of the second part 720 in the x-axis direction. The second region 802 may correspond to a portion of the second part 720 in the -x-axis direction. The third region 803 may a portion between the x-axis direction and the -x-axis direction, corresponding to the shielding member 810. According to various embodiments, when the second part 720 is integrally formed, a portion of the first flexible printed circuit board 510 disposed under the shielding member 810 (e.g., in the z-axis direction) may not directly face the first hinge module 201. For example, when the second part 720 is integrally formed, at least a portion of the third region 803 of the second part 720 may be disposed to spatially face the first hinge module 201.

According to an embodiment, the second part 720 may include a hook (not illustrated) configured to prevent the first flexible printed circuit board 510 disposed on an upper side (e.g., in the -z-axis direction) from being separated. Curvature may be formed at predetermined positions (e.g., in the -z-axis direction) of the first region 801 and the second region 802 of the second part 720 so that the first flexible printed circuit board 510 is bent gently or flexibly.

According to an embodiment, the second part 720 may include a cushioning material. For example, when movement occurs in the first flexible printed circuit board 510 as the first housing 210 and the second housing 220 are folded or unfolded using the first hinge module 201, the second part 720 including the cushioning material may flexibly absorb an impact transmitted through the movement of the first flexible printed circuit board 510.

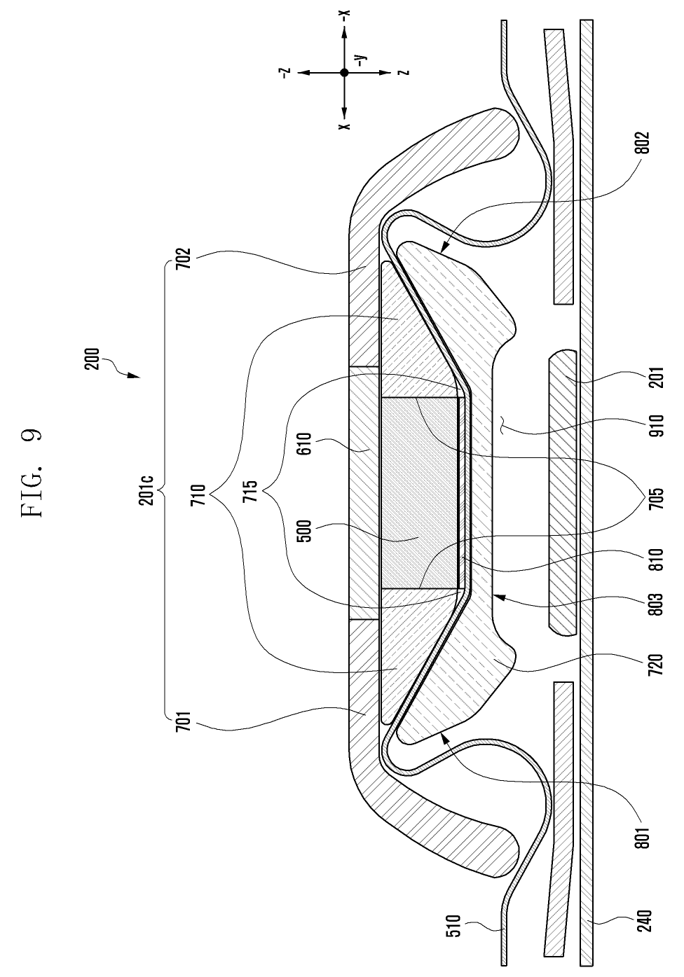

FIG. 9 is a cross-sectional view schematically illustrating a partial configuration of a portion taken along line A-A' of FIG. 6 of the foldable electronic device according to an embodiment of the disclosure.

According to some embodiments, FIG. 9 may be a schematic view illustrating a partial configuration of a cross-sectional view taken along line A-A' of FIG. 6 of the foldable electronic device 200 (e.g., a multi-foldable electronic device), as viewed in the -y-axis direction. For example, FIG. 9 may be a schematic view illustrating a configuration in which the first housing 210 and the second housing 220 of the foldable electronic device 200 illustrated in FIG. 7 are omitted.

According to various embodiments, the embodiments of the foldable electronic device 200 illustrated in FIGS. 7 and 8 may be integrated into and applied to the embodiment illustrated in FIG. 9. The embodiments of the foldable electronic device 200 illustrated in FIG. 9 may also be integrated into and applied to the embodiment illustrated in FIG. 8.

Referring to FIG. 9, compared to the foldable electronic device 200 illustrated in FIG. 8, the foldable electronic device 200 illustrated in FIG. 9 may differ only in that the second part 720 includes a groove 910 formed at a predetermined position (e.g., in the z-axis direction), and other configurations may be substantially the same. Hereinafter, in the foldable electronic device 200 illustrated in FIG. 9, only configurations different from those of the foldable electronic device 200 illustrated in FIG. 8 will be described.

According to various embodiments, the second part 720 may include a groove 910 formed at a predetermined position. For example, the second part 720 may include a groove 910 formed in the z-axis direction. For example, the groove 910 may be formed in the third region 803 of the second part 720. For example, the groove 910 may be formed by removing a portion of the first region 801, the third region 803, and a portion of the second region 802 of the second part 720.

According to another embodiment, when the first housing 210 and the second housing 220 are folded, the groove 910 formed in the second part 720 may be formed at a position corresponding to the first hinge module 201. For example, when the groove 910 is formed at a position corresponding to the first hinge module 201, transmission of the impact to the entirety of the foldable electronic device 200 may be mitigated even if an impact occurs in the folded state of the first housing 210 and the second housing 220. According to various embodiments, when the first housing 210 and the second housing 220 are folded or unfolded, the groove 910 formed in the second part 720 may ensure mobility of the first hinge module 201.

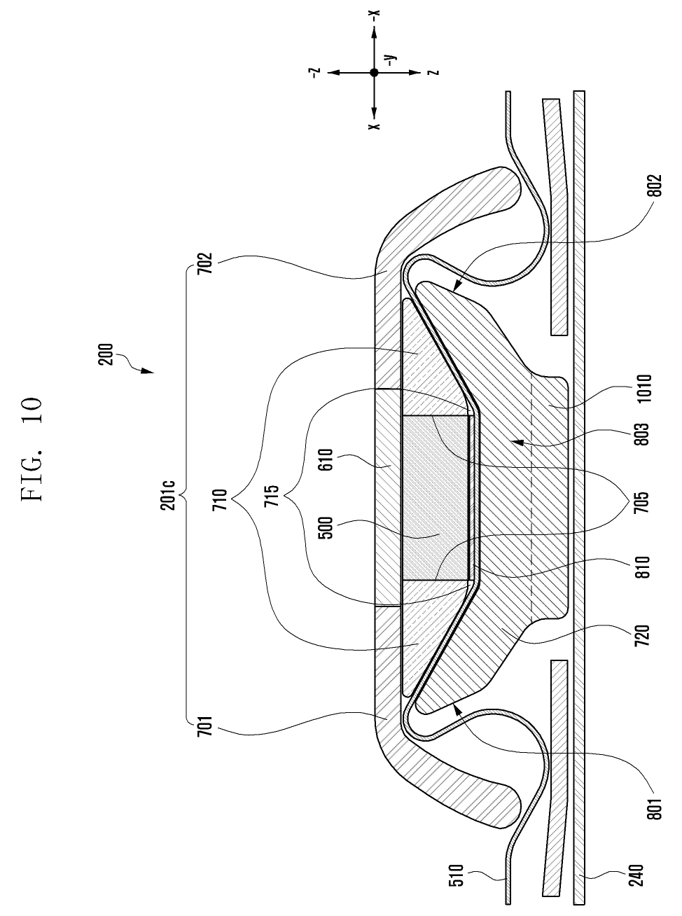

FIG. 10 is a cross-sectional view schematically illustrating a partial configuration of a portion taken along line A-A′ of FIG. 6 of the foldable electronic device according to an embodiment of the disclosure.

According to various embodiments, FIG. 10 may be a schematic view illustrating a partial configuration of a cross-sectional view taken along line A-A′ of FIG. 6 of the foldable electronic device 200 (e.g., a multi-foldable electronic device), as viewed in the -y-axis direction. For example, FIG. 10 may be a schematic view illustrating a configuration in which the first housing 210 and the second housing 220 of the foldable electronic device 200 illustrated in FIG. 7 are omitted.

The embodiments of the foldable electronic device 200 illustrated in FIGS. 8 and 9 may be integrated into and applied to the embodiment illustrated in FIG. 10. The embodiments of the foldable electronic device 200 illustrated in FIG. 10 may also be integrated into and applied to the embodiment illustrated in FIGS. 8 and 9.

Referring to FIG. 10, compared to the foldable electronic device 200 illustrated in FIG. 8, the foldable electronic device 200 illustrated in FIG. 10 may differ only in that the second part 720 includes an extension region 1010 formed at a predetermined position (e.g., in the z-axis direction), and other configurations may be substantially the same. Hereinafter, in the foldable electronic device 200 illustrated in FIG. 10, only configurations different from those of the foldable electronic device 200 illustrated in FIG. 8 will be described.

According to various embodiments, the second part 720 may include an extension region 1010 formed at a predetermined position. For example, the second part 720 may include an extension region 1010 formed in the z-axis direction. For example, the extension region 1010 may be formed in the third region 803 of the second part 720. For example, the extension region 1010 may be formed by a portion of the first region 801, the third region 803, and a portion of the second region 802 of the second part 720. For example, the extension region 1010 may be formed to integrally extend from the third region 803 of the second part 720.

According to another embodiment, when the second part 720 includes the extension region 1010, at least a portion of the first hinge module 201 may be omitted or removed. The extension region 1010 of the second part 720 may partially support a portion of the flexible display 240.

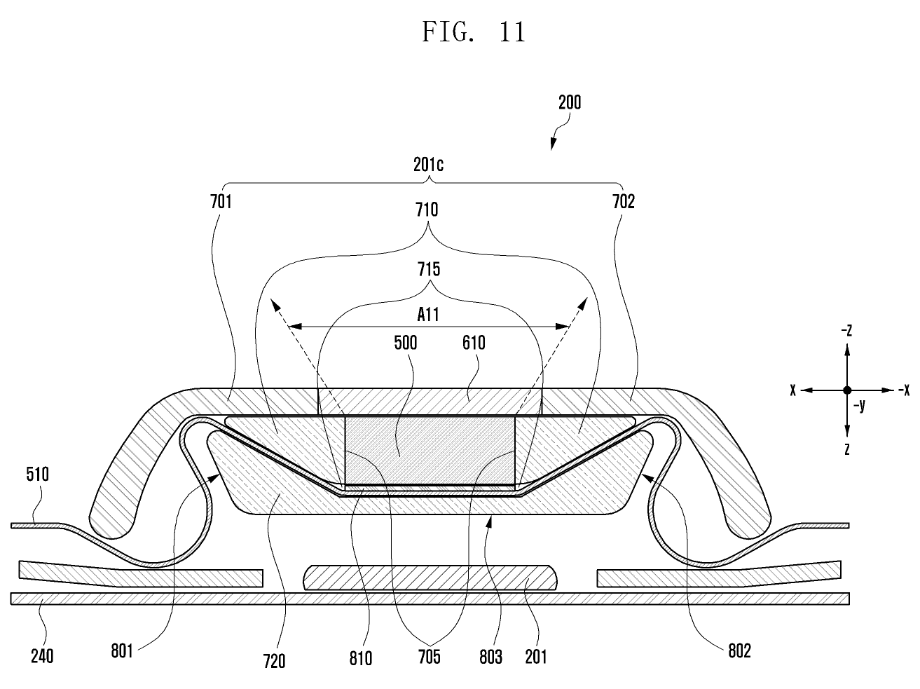

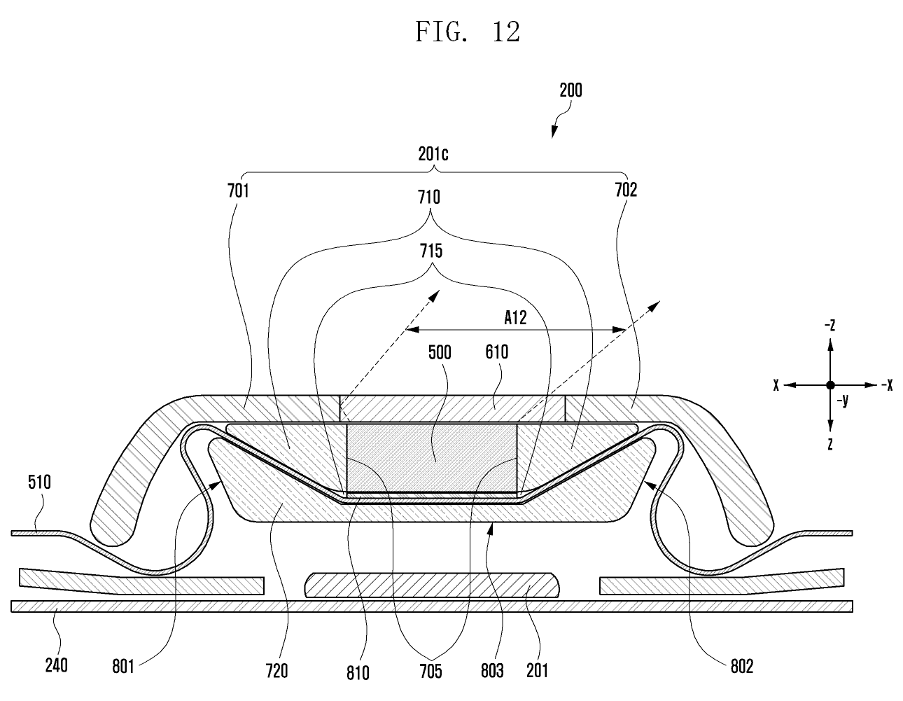

FIG. 11 is a view schematically illustrating a first radiation region of a foldable electronic device according to an embodiment of the disclosure. FIG. 12 is a view schematically illustrating a second radiation region of the foldable electronic device according to an embodiment of the disclosure.

According to various embodiments, FIGS. 11 and 12 may each be a schematic view illustrating a partial configuration of a portion taken along line A-A' of the foldable electronic device 200 (e.g., a multi-foldable electronic device) of FIG. 6, as viewed in the -y-axis direction.

According to various embodiments, the embodiments of the foldable electronic device 200 illustrated in FIGS. 11 and 12 may be integrated into and applied to the embodiments illustrated in FIGS. 7 to 10. In an embodiment, the foldable electronic device 200 illustrated in FIGS. 11 and 12 may include substantially the same embodiments as those illustrated in FIG. 8.

Referring to FIG. 11, the first hinge cover 201c may include a non-conductive portion 610 in at least a portion thereof. The non-conductive portion 610 may be partially formed in the first hinge cover 201c. The non-conductive portion 610 may be disposed to overlap the antenna module 500. For example, the non-conductive portion 610 may be formed at a position corresponding to the antenna module 500. For example, the non-conductive portion 610 may be formed in a central region of the first hinge cover 201c. For example, the non-conductive portion 610 may be formed between a first portion 701 (e.g., in the x-axis direction) and a second portion 702 (e.g., in the -x-axis direction) of the first hinge cover 202c. Portions of the first hinge cover 201c other than the non-conductive portion 610 may be formed of a conductive material (e.g., metal).

The non-conductive portion 610 may be disposed at a central position between the first portion 701 (e.g., in the x-axis direction) and the second portion 702 (e.g., in the -x-axis direction) of the first hinge cover 201c. For example, the non-conductive portion 610 may be disposed at the central position between the first portion 701 and the second portion 702 of the first hinge cover 201c and may overlap the antenna module 500. For example, the antenna module 500 may secure a radiation region without being affected by an end portion of the first portion 701 in the -x-axis direction and an end portion of the second portion 702 in the x-axis direction, which are conductive portions of the first hinge cover 201c. For example, when the non-conductive portion 610 is disposed at the central position between the first portion 701 and the second portion 702 of the first hinge cover 201c and is not affected by the end portion of the first portion 701 in the -x-axis direction and the end portion of the second portion 702 in the x-axis direction, the antenna module 500 may perform radiation toward the first radiation region A11 (e.g., in the -z-axis direction).

Referring to FIG. 12, the non-conductive portion 610 may be formed and disposed at a position shifted in the -x-axis direction from the central region of the first hinge cover 201c. For example, one end portion (e.g., in the x-axis direction) of the non-conductive portion 610 may be disposed adjacent to one end portion (e.g., in the x-axis direction) of the antenna module 500. When the one end portion (e.g., in the x-axis direction) of the non-conductive portion 610 is disposed adjacent to the one end portion (e.g., in the x-axis direction) of the antenna module 500, the one end portion (e.g., in the x-axis direction) of the antenna module 500 may be adjacent to an end portion of the first portion 701 in the -x-axis direction, which is a conductive portion of the first hinge cover 201c.

According to an embodiment, when the non-conductive portion 610 is disposed at a position shifted in the -x-axis direction from the central region of the first hinge cover 201c, the antenna module 500 may be affected by the end portion of the first portion 701 in the -x-axis direction, which is a conductive portion of the first hinge cover 201c, and thus a radiation region may be changed. For example, when the non-conductive portion 610 is disposed at a position shifted in the -x-axis direction from the central region of the first hinge cover 201c and is affected by the end portion of the first portion 701 in the -x-axis direction, the antenna module 500 may perform radiation toward, for example, the second radiation region A12 between the -z-axis direction and the -x-axis direction. In an example, when the non-conductive portion 610 is at least partially misaligned with the antenna module 500, the radiation region of the antenna module 500 may be changed. According to various embodiments, the first hinge cover 201c may change the radiation region by moving and disposing the non-conductive portion 610 at various positions. For example, when an overlapping and/or alignment position between the non-conductive portion 610 of the first hinge cover 501c and the antenna module 500 is variously changed, the antenna module 500 may secure various radiation regions.

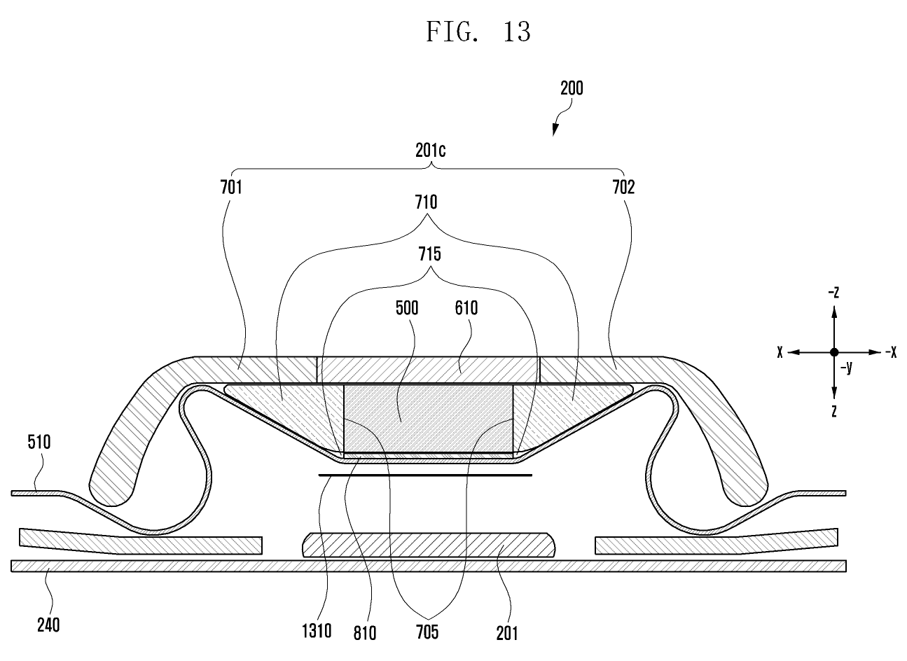

FIG. 13 is a cross-sectional view schematically illustrating a partial configuration of a portion taken along line A-A′ of FIG. 6 of the foldable electronic device according to an embodiment of the disclosure.

According to various embodiments, FIG. 13 may be a schematic view illustrating a partial configuration of a cross-sectional view taken along line A-A′ of FIG. 6 of the foldable electronic device 200 (e.g., a multi-foldable electronic device), as viewed in the -y-axis direction.

According to various embodiments, the embodiments of the foldable electronic device 200 illustrated in FIGS. 7 to 12 may be integrated into and applied to the embodiment illustrated in FIG. 13. The embodiments of the foldable electronic device 200 illustrated in FIG. 13 may also be integrated into and applied to the embodiment illustrated in FIGS. 7 to 12.

Referring to FIG. 13, the foldable electronic device 200 illustrated in FIG. 13 may differ from the foldable electronic device 200 illustrated in FIG. 8 only in that the second part 720 is omitted or removed and a protective member 1310 (e.g., a thin film sheet or a thin film layer) is included, and other configurations may be substantially the same. Hereinafter, in the foldable electronic device 200 illustrated in FIG. 13, only configurations different from those of the foldable electronic device 200 illustrated in FIG. 8 will be described.

According to various embodiments, the foldable electronic device 200 may not include the second part 720. For example, in the foldable electronic device 200 illustrated in FIG. 13, the second part 720 may be omitted or removed. For example, the protective member 1310 may be disposed between a portion of the first flexible printed circuit board 510 and the first hinge module 201. The protective member 1310 may include a thin film sheet or a thin film layer. The protective member 1310 may prevent direct contact between the portion of the first flexible printed circuit board 510 and the first hinge module 201. The protective member 1310 may be applied when a space between the portion of the first flexible printed circuit board 510 and the first hinge module 201 is narrow. The protective member 1310 may be applied when a range of movement of the first hinge module 201 is wide.

According to an embodiment, a foldable electronic device 200 may include a first housing 210, a second housing 220, a first hinge module 201 disposed between the first housing 210 and the second housing 220, a flexible display 240 disposed on the first housing 210 and the second housing 220, and a first hinge cover 201c configured to cover the first hinge module 201. According to an embodiment, the foldable electronic device 200 may include a first flexible printed circuit board 510 disposed between the first hinge module 201 and the first hinge cover 201c, and an antenna module 500 including a plurality of patch antennas and disposed between the first flexible printed circuit board 510 and the first hinge cover 201c.

According to an embodiment, the foldable electronic device 200 may further include a guide structure 700 attached to an inner surface of the first hinge cover 201c, and the guide structure 700 may include an accommodation space 705 configured to accommodate the antenna module 500 and may be configured to guide a portion of the first flexible printed circuit board 510 extending across the first hinge cover 201c.

The guide structure 700 may include a first part 710 attached to the inner surface of the first hinge cover 201c, and the first flexible printed circuit board 510 may be disposed between the first part 710 and the first hinge module 201.

According to an embodiment, the guide structure 700 may further include a second part 720 disposed between the first hinge module 201 and the first flexible printed circuit board 510, and the first flexible printed circuit board 510 may be disposed within a gap 715 formed between the first part 710 and the second part 720.

According to an embodiment, at least a portion of the second part 720 may include a first portion 720a and a second portion 720b separated from each other with reference to a placement position of the antenna module 500.

According to an embodiment, at least a portion of the first part 710 and the second part 720 may be integrally connected. According to an embodiment, the first hinge cover 201c may include a non-conductive portion 610, and the antenna module 500 may be disposed at a position overlapping the non-conductive portion 610.

At least a portion of the first part 710 may include a first inclined surface 711.

According to an embodiment, at least a portion of the second part 720 may include a second inclined surface 712.

According to an embodiment, the first inclined surface 711 and the second inclined surface 712 may have substantially the same inclination.

According to an embodiment, the foldable electronic device 200 may further include a shielding member 810 disposed between the antenna module 500 and the first flexible printed circuit board 510.

According to another embodiment, the first housing 210 may include a first printed circuit board 501, the second housing 220 may include a second printed circuit board 502, and the first flexible printed circuit board 510 may be configured to electrically connect the first printed circuit board 501 and the second printed circuit board 502 across a portion of the first hinge cover 201c.

According to an embodiment, the antenna module 500 may be electrically connected to a wireless communication module 192 disposed on the first printed circuit board 501 by using a second flexible printed circuit board 520.

According to an embodiment, the foldable electronic device 200 may further include a third housing 230, a second hinge module 202 disposed between the first housing 210 and the third housing 230, and a second hinge cover 202c configured to cover the second hinge module 202, and the width of the first hinge cover 201c may be greater than the width of the second hinge cover 202c.

The first hinge module 201 may include an in-folding hinge configured to fold in an in-folding manner, and the second hinge module 202 may include an in-folding hinge configured to fold in an in-folding manner.

According to an embodiment, the second part 720 may include a cushioning material.

According to another embodiment, the second part 720 may include a first region 801, a second region 802, and a third region 803 integrally formed with each other, and at least a portion of the third region 803 may be formed at a position facing the first hinge module 201.

According to an embodiment, the foldable electronic device 200 may include a groove 910 formed in the third region 803 of the second part 720.

According to an embodiment, the foldable electronic device 200 may include an extension region 1010 integrally extending from the third region 803 of the second part 720.

According to an embodiment, the foldable electronic device 200 may be configured such that a radiation region of the antenna module 500 is changed when the antenna module 500 and the non-conductive portion 610 are arranged in a misaligned manner.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A foldable electronic device comprising:
a first housing;
a second housing;
a first hinge disposed between the first housing and the second housing;
a flexible display disposed on the first housing and the second housing;
a first hinge cover configured to cover the first hinge;
a first flexible printed circuit board disposed between the first hinge and the first hinge cover; and
an antenna including a plurality of patch antennas and disposed between the first flexible printed circuit board and the first hinge cover.

2. The foldable electronic device of claim 1, further comprising:
a guide structure attached to an inner surface of the first hinge cover,
wherein the guide structure includes an accommodation space configured to accommodate the antenna, and is configured to guide a portion of the first flexible printed circuit board extending across the first hinge cover.

3. The foldable electronic device of claim 2,
wherein the guide structure includes a first part attached to an inner surface of the first hinge cover, and
wherein the first flexible printed circuit board is disposed between the first part and the first hinge.

4. The foldable electronic device of claim 3,
wherein the guide structure further includes a second part disposed between the first hinge and the first flexible printed circuit board, and
wherein the first flexible printed circuit board is disposed within a gap formed between the first part and the second part.

5. The foldable electronic device of claim 4,
wherein at least a portion of the second part includes a first portion and a second portion separated from each other with reference to a placement position of the antenna.

6. The foldable electronic device of claim 5,
wherein at least a portion of the first part and the second part are integrally connected.

7. The foldable electronic device of claim 5,
wherein the first hinge cover includes a non-conductive portion, and
wherein the antenna is disposed at a position overlapping the non-conductive portion.

8. The foldable electronic device of claim 5,
wherein at least a portion of the first part includes a first inclined surface.

9. The foldable electronic device of claim 8,
wherein at least a portion of the second part includes a second inclined surface.

10. The foldable electronic device of claim 9,
wherein the first inclined surface and the second inclined surface have substantially the same inclination.

11. The foldable electronic device of claim 1, further comprising:
a shielding member disposed between the antenna and the first flexible printed circuit board.

12. The foldable electronic device of claim 1,
wherein the first housing includes a first printed circuit board,
wherein the second housing includes a second printed circuit board, and
wherein the first flexible printed circuit board is configured to electrically connect the first printed circuit board and the second printed circuit board across a portion of the first hinge cover.

13. The foldable electronic device of claim 12, wherein the antenna is electrically connected to a wireless communication device disposed on the first printed circuit board by using a second flexible printed circuit board.

14. The foldable electronic device of claim 13, further comprising:
a third housing;
a second hinge disposed between the first housing and the third housing; and
a second hinge cover configured to cover the second hinge,
wherein a width of the first hinge cover is configured to be greater than a width of the second hinge cover.

15. The foldable electronic device of claim 14,
wherein the first hinge includes an in-folding hinge configured to fold in an in-folding manner, and
wherein the second hinge includes an in-folding hinge configured to fold in an in-folding manner.

16. The foldable electronic device of claim 4,
wherein the second part includes cushioning material.

17. The foldable electronic device of claim 4,
wherein the second part includes a first region, a second region, and a third region integrally formed with each other, and
wherein at least a portion of the third region is formed at a position facing the first hinge.

18. The foldable electronic device of claim 17, further comprising:
a groove formed in the third region of the second part.

19. The foldable electronic device of claim 17, further comprising:
an extension region integrally extending from the third region of the second part.

20. The foldable electronic device of claim 7, wherein the antenna is configured such that a radiation region is changed when the antenna and the non-conductive portion are arranged in a misaligned manner.
